(19) United States
(12) Patent Application Publication
(10) Pub. No.: US 2021/0074331 A1
(43) Pub. Date: Mar. 11, 2021

(54) SERVER

(71) Applicants: INVENTEC (PUDONG) TECHNOLOGY CORPORATION, Shanghai City (CN); INVENTEC CORPORATION, Taipei City (TW)

(72) Inventors: Shu-Min WANG, Shanghai City (CN); Ji-Peng XU, Shanghai City (CN)

(73) Assignees: INVENTEC (PUDONG) TECHNOLOGY CORPORATION, Shanghai City (CN); INVENTEC CORPORATION, Taipei City (TW)

(21) Appl. No.: 16/572,108

(22) Filed: Sep. 16, 2019

(30) Foreign Application Priority Data
Sep. 5, 2019 (CN) 201910837616.7

(51) Int. Cl. G11B 33/12; H05K 7/20; H05K 7/14

(52) U.S. Cl. CPC G11B 33/125; H05K 7/1487; H05K 7/20727

(57) ABSTRACT

A server includes a case including a bottom board, a first lateral board and a second lateral board, a riser card provided with opposite two ends respectively disposed on the lateral boards, a HDD backplane electrically connected with the riser card, first HDDs disposed on the HDD backplane, a first main logic board electrically connected with the riser card, and a common carrier. The lateral boards are respectively located on opposite sides of the bottom board, and an accommodation space is formed between the lateral boards. The riser card divides the accommodation space into a two accommodation regions. The HDD backplane is disposed in a first accommodation region. The first main logic board is disposed in a second accommodation region, and the first HDDs is electrically connected with the first main logic board via the riser card. The common carrier is disposed in the second accommodation region.

### CROSS-REFERENCE TO RELATED APPLICATIONS

This non-provisional application claims priority under 35 U.S.C. § 119(a) on Patent Application No(s). 201910837616.7 filed in China on Sep. 5, 2019, the entire contents of which are hereby incorporated by reference.

### BACKGROUND OF THE INVENTION

### 1. Technical Field

This present disclosure relates to a server, more particular to a server in which the number of the hard disk drive (HDD) can be adjusted.

### 2. Related Art

A server is an electronic equipment including central processing unit (CPU), memories, input/output (I/O) and other components, and these components are connected together connected by multiple buses. The server can be served for file sharing, databases, email, network applications and so on, or can provide specific functions such as data storage.

Conventionally, the server has fixed amount of interior space for accommodating HDDs. As the demand for data storage has increased, additional HDDs are needed in order to provide sufficient storage capacity to meet specific requirements. However, it is understood that the carrier in the conventional server cannot provide more space for accommodating additional HDDs. A design of server is not only to focus on processor and memory efficiency but also to have another carrier to provide extra space for accommodating additional HDDs, such that the number of HDDs is increased greatly. Such kind of server, which can install a large number of HDDs, is called high storage density server.

### SUMMARY OF THE INVENTION

According to one aspect of the present disclosure, a server includes a case including a bottom board, a first lateral board and a second lateral board, a riser card provided with opposite two ends respectively disposed on the first lateral board and the second lateral board, a HDD backplane electrically connected with the riser card, a plurality of first HDDs disposed on the HDD backplane, a first main logic board electrically connected with the riser card, and a common carrier. The first lateral board and the second lateral board are respectively located on opposite sides of the bottom board, and an accommodation space is formed between the first lateral board and the second lateral board. The riser card divides the accommodation space into a first accommodation region and a second accommodation region. The HDD backplane is disposed in the first accommodation region. The first main logic board is disposed in the second accommodation region, and the first HDDs is electrically connected with the first main logic board via the riser card. The common carrier is disposed in the second accommodation region.

The server at a first mode accommodates more HDDs than that at a second mode. At the first mode of the server, a plurality of second HDDs are disposed on the common carrier. The second HDDs are electrically connected with the first main logic board via the riser card. At the second mode of the server, a second main logic board is disposed on the common carrier, and the first HDDs are electrically connected with the second main logic board via the riser card.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a perspective view of a server according to one embodiment of the present disclosure;

FIG. 2 is an exploded view of the server in FIG. 1;

FIG. 3 is a partially exploded view of the server in FIG. 1 at a first mode;

FIG. 4 is a partially exploded view of the server in FIG. 1 at a second mode; and

FIG. 5 is a perspective view showing a server mounted on a rack according to another embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

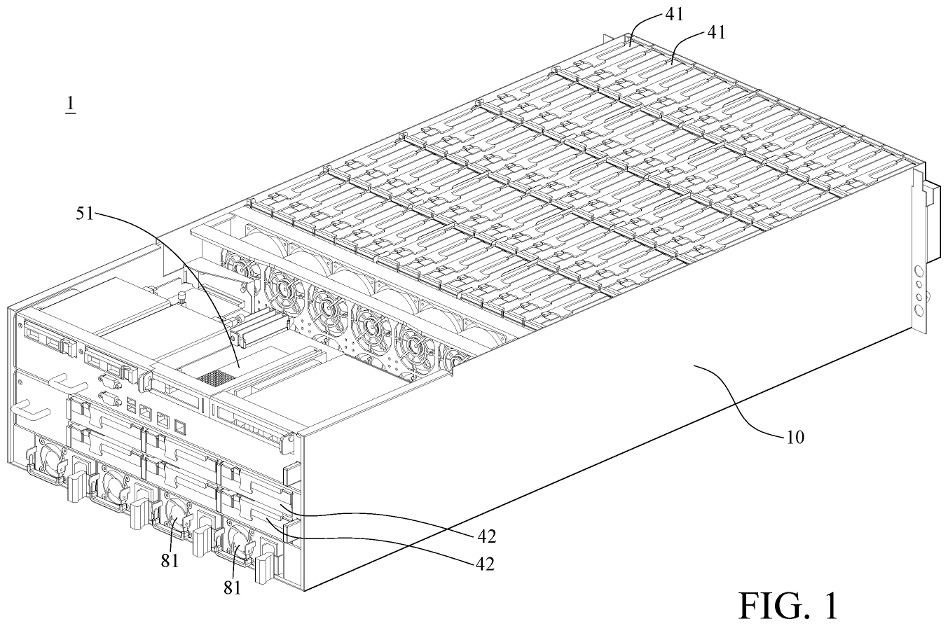

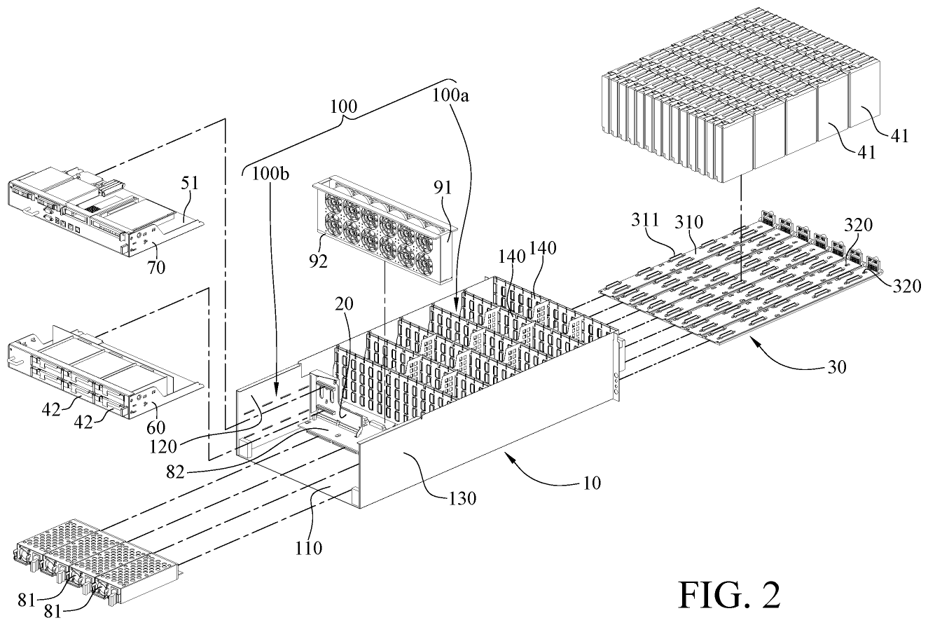

According to one embodiment of the present disclosure, a server includes a case, a riser card, a HDD backplane, at least one first HDD, a first main logic board and a common carrier. Please refer to FIG. 1 and FIG. 2. FIG. 1 is a perspective view of a server according to one embodiment of the present disclosure, and FIG. 2 is an exploded view of the server in FIG. 1. In this embodiment, a server 1 includes a case 10, a riser card 20, a HDD backplane 30, a plurality of first HDDs 41, a first main logic board 51 and a common carrier 60.

The case 10 includes a bottom board 110, a first lateral board 120 and a second lateral board 130. The first lateral board 120 and the second lateral board 130 are located on opposite sides of the bottom board, respectively. An accommodation space 100 is formed between the first lateral board 120 and the second lateral board 130. The case 10 can further includes a top board configured to cover the elements in the accommodation space 100, while the top board is omitted in the drawings for the purpose of clear illustration.

The riser card 20 has opposite ends which are disposed on the first lateral board 120 and the second lateral board 130, respectively. The riser card 20 divides the accommodation space 100 into a first accommodation region 100a and a second accommodation region 100b. In this embodiment, the first accommodation region 100a is larger than the second accommodation region 100b, but the present disclosure is not limited to the size of the accommodation region.

The HDD backplane 30 is disposed in the first accommodation region 100a, and the HDD backplane 30 is electrically connected with the riser card 20. In detail, the HDD backplane 30 is movably disposed in the first accommodation region 100a to be moved close to or away from the riser card 20. The riser card 20 can includes at least one port, and the HDD backplane 30 is detachably inserted into the port to be electrically connected with the riser card 20.

The first HDDs 41 are disposed on the HDD backplane 30. In detail, the HDD backplane 30 includes a circuit board 310, and the circuit board 310 has a plurality of slots 311. The first HDD 41 is inserted into respective slot 311 to be electrically connected with the riser card 20 via the circuit board 310. In this embodiment, the case 10 further includes a plurality of partitions 140 which are disposed in the first accommodation region 100a and are arranged in parallel. A row of first HDDs 41 is constrained by adjacent partitions 140 so as to prevent unpredictable separation of the first HDD 41 from the slot 311.

The first main logic board 51 is disposed in the second accommodation region 100b and is electrically connected with the riser card 20. The first HDDs 41 are electrically connected with the first main logic board 51 via the riser card 20. In this embodiment, the server 1 further includes a logic board carrier 70 disposed in the second accommodation region 100b, and the first main logic board 51 is disposed on the logic board carrier 70.

The common carrier 60 is disposed in the second accommodation region 100b. In this embodiment, the common carrier 60 is disposed between the logic board carrier 70, on which the first main logic board 51 is supported, and the bottom board 110 of the case 10. It is noted that the present disclosure does not limited to the aforementioned configuration. In some embodiments, the common carrier can be located on the same level as the first main logic board, or the common carrier can be disposed in the first accommodation region. A configuration in this embodiment that the common carrier 60 is disposed between the first main logic board 51 and the bottom board 110 is favorable for providing sufficient amount of space in the case for accommodating other electronic components.

According to one embodiment of the present disclosure, the server further includes a power supply unit and a power distribution unit. As shown in FIG. 2, the server 1 further includes a power supply unit 81 and a power distribution unit 82. The power supply unit 81 is disposed in the second accommodation region 100b, and the power supply unit 81 is disposed between the common carrier 60 and the bottom board 110 of the case 10. The power supply unit 81 and the riser card 20 are electrically connected with the power distribution unit 82. The power supply unit 81 supply electric power to the first main logic board 51 and the HDD backplane 30 via the power distribution unit 82 and the riser card 20.

According to one embodiment of the present disclosure, the server further includes a heat dissipation fan and a fan control board. As shown in FIG. 2 the server 1 further includes a heat dissipation fan 91 and a fan control board 92. The heat dissipation fan 91 is disposed between the first HDDs 41 and the first main logic board 51, and the heat dissipation fan is electrically connected with the fan control board 92.

According to one embodiment of the present disclosure, the HDD backplane includes a circuit board and a plurality of indicator lights located on the circuit board. As shown in FIG. 2, the HDD backplane 30 further includes a plurality of indicator lights 320 located on the circuit board 310. The indicator lights 320 correspond to the first HDDs 41, respectively, for identifying the working state of respective first HDDs 41. For example, when the first HDD 41 works normally, the corresponding indicator light 320 emits green light. When the first HDD 41 is failed, the corresponding indicator light 320 emits red light.

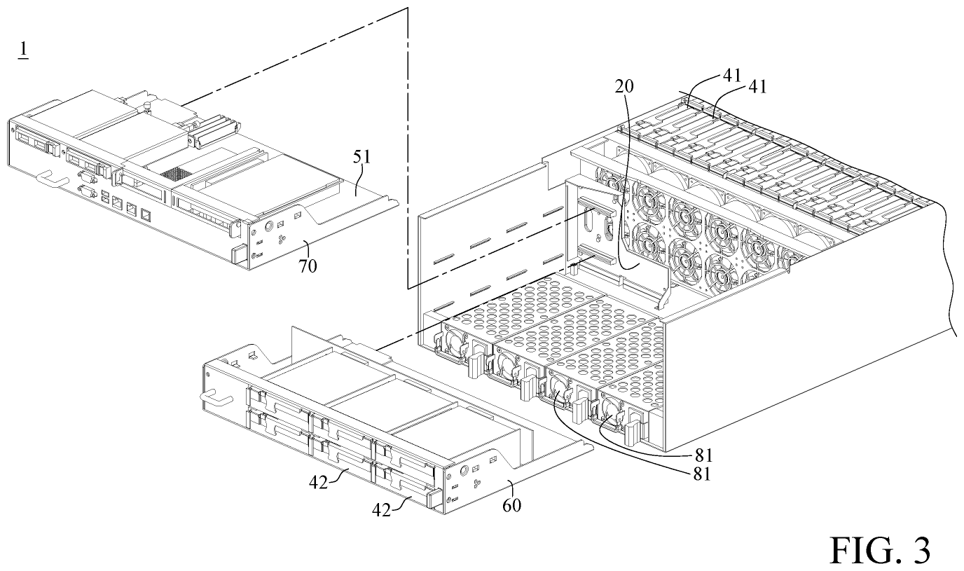

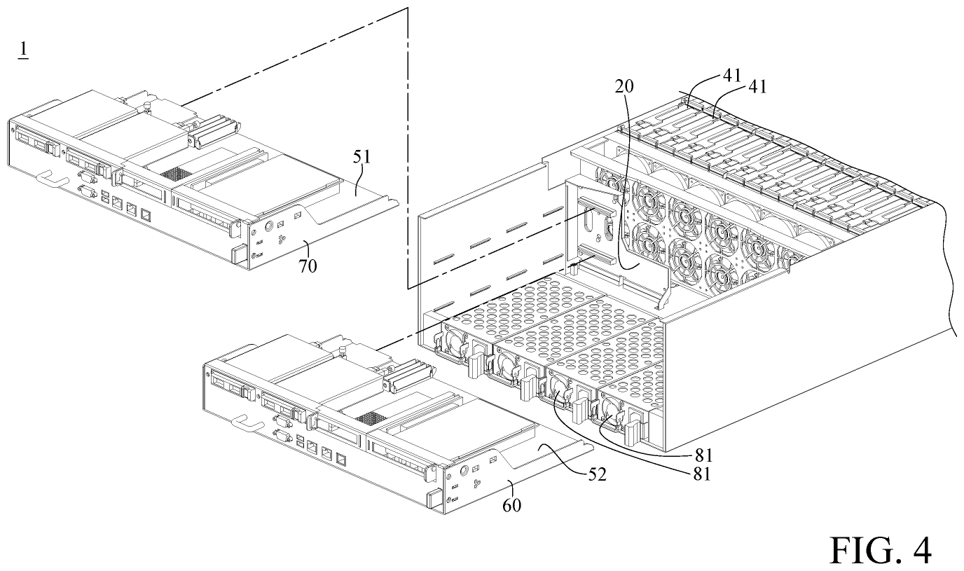

According to one embodiment of the present disclosure, the server has at least two modes for satisfying different requirements. Please refer to FIG. 3 and FIG. 4. FIG. 3 is a partially exploded view of the server in FIG. 1 at a first mode. FIG. 4 is a partially exploded view of the server in FIG. 1 at a second mode.

As shown in FIG. 3, in this embodiment, when the server 1 is at the first mode, a plurality of second HDDs 42 are disposed on the common carrier 60, and the second HDDs 42 is electrically connected with the first main logic board 51 via the riser card 20. In detail, at the first mode, additional HDD backplane can be disposed on the common carrier 60, and the second HDDs 42 are inserted into respective slots on that HDD backplane to be electrically connected with the riser card 20. Thus, the server 1 at the first mode has large amount of HDDs for meeting the requirement of high storage capacity. In one embodiment, the server 1 includes a total of 70 first HDDs 41, and 6 second HDDs 42 are disposed when the server 1 is at the first mode. Therefore, the server 1 at the first mode includes a total of 76 HDDs to achieve a total storage capacity (the capacity of first HDDs 41 and second HDDs 42) of 380 TB (Terabyte).

As shown in FIG. 3, in this embodiment, when the server 1 is at the second mode, a second main logic board 52 is disposed on the common carrier 60, and the first HDDs 41 are electrically connected with second main logic board 52 via the riser card 20. In detail, at the second mode, additional main logic board can be disposed on the common carrier 60, and the second main logic board 52 supported on the common carrier 60 is electrically connected with the riser card 20. The first HDDs are electrically connected with the second main logic board 52 via the riser card 20. Thus, the server 1 at the second mode includes multiple main logic boards (the first main logic board 51 and the second main logic board 52) configured to process data delivered from the first HDDs 41, and multiple main logic boards are favorable for increasing the speed of processing data to meet the requirement of high speed delivery. The server 1 at the first mode accommodates more HDDs than that at the second mode. In one embodiment, as shown in FIG. 3, the server 1 accommodates 76 HDDs at the first mode; as shown in FIG. 4, the server 1 accommodates a total of 70 HDDs (first HDDs 41) to achieve a storage capacity of at least 280 TB.

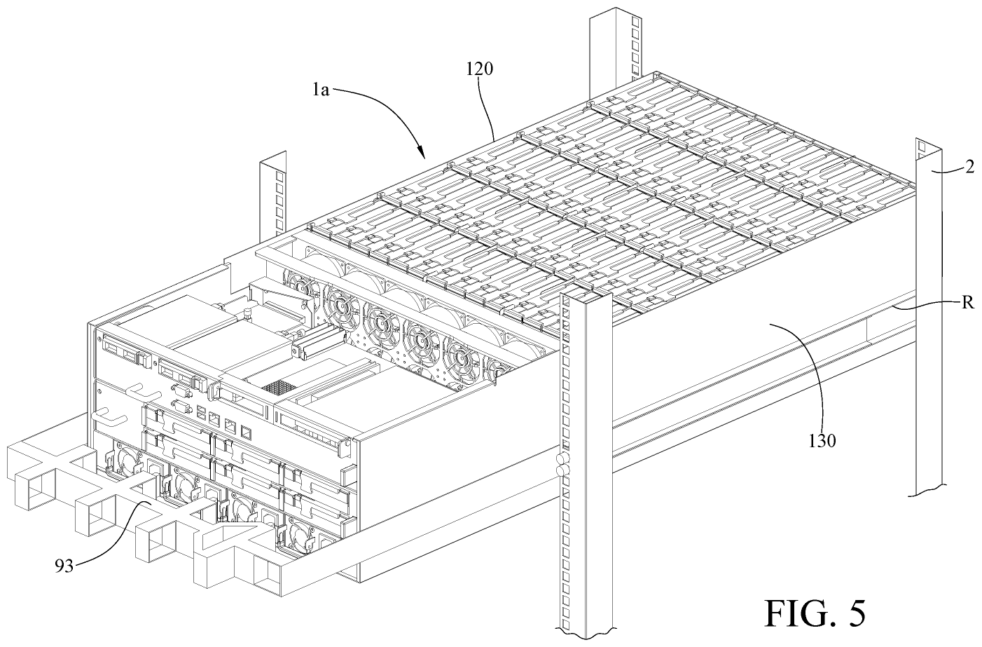

FIG. 5 is a perspective view showing a server mounted on a rack according to another embodiment of the present disclosure. A server 1a further includes a cable management arm 93, and at least one of the first lateral board 120 and the second lateral board 130 of the case 10 has an outer surface on which a sliding rail is located. In this embodiment, each of the first lateral board 120 and the second lateral board 130 has a sliding rail R on the outer surface. The server 1a is disposed on the sliding rails R to be slidable relative to a rack 2. The elements accommodated in the server 1a can be referred to the server depicted in FIG. 1. The cable management arm 93 is disposed in the sliding rails R, such that the server 1a can be pulled out of the rack for maintenance even though it is working, and thus the maintenance of elements inside the server does not apply negative influence on the working server 1a.

According to the present disclosure, the server includes different amount of HDDs at different modes. At the first mode, the common carrier supports additional HDDs such that the server accommodates more HDDs for the requirement of high storage capacity. At the second mode, the common carrier supports additional main logic board such that the server accommodates more main logic boards to process data, thereby meeting the requirement of high speed data delivery. Since different elements can be disposed on the common carrier according to various requirements, the server in the present disclosure is widely used under various applications.

It will be apparent to those skilled in the art that various modifications and variations can be made to the present disclosure. It is intended that the specification and examples be considered as exemplary embodiments only, with a scope of the disclosure being indicated by the following claims and their equivalents.

1. A server, comprising:
a case comprising a bottom board, a first lateral board and a second lateral board, the first lateral board and the second lateral board being respectively located on opposite sides of the bottom board, and an accommodation space being formed between the first lateral board and the second lateral board;
a riser card provided between the first lateral board and the second lateral board, and the riser card dividing the accommodation space into a first accommodation region and a second accommodation region; and
a hard disk drive (HDD) backplane disposed in the first accommodation region, and the HDD backplane being electrically connected with the riser card;
a plurality of first HDDs disposed on the HDD backplane;
a first main logic board disposed in the second accommodation region and electrically connected with the riser card, and the plurality of first HDDs being electrically connected with the first main logic board via the riser card; and
a common carrier disposed in the second accommodation region;
wherein the server at a first mode accommodates more HDDs than that at a second mode,
at the first mode of the server, a plurality of second HDDs are disposed on the common carrier, the plurality of second HDDs being electrically connected with the first main logic board via the riser card, and
at the second mode of the server, a second main logic board disposed on the common carrier, and the plurality of first HDDs being electrically connected with the second main logic board via the riser card.

2. The server of claim 1, wherein the common carrier is disposed between the first main logic board and the bottom board of the case.

3. The server of claim 1, further comprising a logic board carrier disposed in the second accommodation region, wherein the first main logic board is disposed on the logic board carrier.

4. The server of claim 1, further comprising a power supply unit disposed in the second accommodation region, wherein the power supply unit is located between the common carrier and the bottom board of the case.

5. The server of claim 4, further comprising a power distribution unit disposed in the case, wherein the power supply unit and the riser card are electrically connected with the power distribution unit.

6. The server of claim 1, further comprising a heat dissipation fan disposed between the plurality of first HDDs and the first main logic board.

7. The server of claim 6, first comprising a fan control board disposed in the case, wherein the heat dissipation fan is electrically connected with the fan control board.

8. The server of claim 1, wherein the HDD backplane comprises a circuit board and a plurality of indicator lights located on the circuit board, and the plurality of indicator lights respectively correspond to the plurality of first HDDs for identifying working state of the plurality of first HDDs.

9. The server of claim 1, further comprising a cable management arm, wherein at least one of the first lateral board and the second lateral board has an outer surface on which a sliding rail is located, and the cable management arm is disposed in the sliding rail.

10. The server of claim 1, wherein the plurality of first HDDs has a storage capacity of 280 TB-380 TB, or the plurality of first HDDs and the plurality of second HDDs has a total storage capacity of 280 TB-380 TB.
